(19) United States
(12) Patent Application Publication
(10) Pub. No.: US 2007/0161144 A1
(43) Pub. Date: Jul. 12, 2007

(54) Method for Manufacturing CMOS Image Sensor

(76) Inventor: Ki Sik Im, Daegu-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/616,114

(22) Filed: Dec. 26, 2006

(30) Foreign Application Priority Data
Dec. 28, 2005 (KR) 10-2005-0132691

(51) Int. Cl. H01L 21/00

(52) U.S. Cl. 438/57; 257/E31.052

(57) ABSTRACT

Provided is a method for manufacturing a CMOS image sensor. In the method, a mask layer is formed on a semiconductor substrate to define a device isolation region. The semiconductor substrate is selectively removed by wet etching using the mask layer as a mask to form a trench to a predetermined depth. A device isolation layer is formed in the trench, and the mask layer is removed. A gate electrode is formed on a gate insulation layer in an active region of the semiconductor substrate defined by the device isolation layer. A photodiode (PD) region is formed in the semiconductor substrate at one side of the gate electrode. A floating diffusion region is formed in the semiconductor substrate at the other side of the gate electrode.

### RELATED APPLICATION(S)

This application claims priority under 35 U.S.C. §119(e) of Korean Patent Application No. 10-2005-0132691 filed Dec. 28, 2005, which is incorporated herein by reference in its entirety.

### FIELD OF THE INVENTION

The present invention relates to a method for manufacturing a complementary metal oxide semiconductor (CMOS) image sensor.

### BACKGROUND OF THE INVENTION

Image sensors are semiconductor devices for converting an optical image into an electrical signal. Image sensors can be classified as a charge coupled device (CCD) or a CMOS image sensor.

A CCD includes a plurality of photodiodes (PDs) arranged in matrix for converting optical signals into electrical signals, a plurality of vertical charge coupled devices (VCCDs) formed between columns of the matrix array of the PDs so as to transfer electric charges generated in the PDs in a vertical direction, a horizontal charge coupled device (HCCD) transferring the electric charges from the VCCDs in a horizontal direction, and a sense amplifier outputting an electrical signal by sensing the electric charges transferred in the horizontal direction.

However, such a CCD is driven by a complicated method and consumes a lot of power. Furthermore, the manufacturing process of the CCD is complex due to a multi-step photo-process.

In addition, it is difficult to integrate components such as a control circuit, a signal processing circuit, and an analog/digital (A/D) converter into a single CCD chip.

Recently, CMOS image sensors are considered to be the next generation of image sensors that can obviate the problems of the CCD.

A CMOS image sensor includes metal oxide semiconductor (MOS) transistors formed in each unit pixel. The MOS transistors are formed on a semiconductor substrate using a CMOS technology with circuits such as a control circuit and a signal processing circuit as peripheral circuits. The CMOS image sensor uses a switching method to sequentially detect outputs of pixels using the MOS transistors.

That is, in each pixel of the CMOS image sensor, a PD and a MOS transistor are formed. Therefore, an image can be formed by sequentially detecting outputs of pixels according to the switching method.

Since the CMOS image sensor is manufactured using CMOS technology, the CMOS image sensor can be manufactured with less cost and photo-processing steps. That is, the CMOS image sensor can be manufactured through a relatively simple process.

Furthermore, it is easy to integrate components such as a control circuit, a signal processing circuit, and an A/D converter into a single CMOS image sensor chip, making it possible to manufacture a small CMOS image sensor.

Therefore, CMOS images sensors are now used in various applications such as digital still cameras and digital video cameras.

CMOS image sensors can be classified as 3T type, 4T type, or 5T type based on the number of transistors formed in each unit pixel. For example, a 3T CMOS image sensor includes one PD and three transistors, and a 4T CMOS image sensor includes one PD and four transistors.

A conventional 4T type CMOS image sensor will now be described.

FIG. 1 is an equivalent circuit diagram of a 4T type CMOS image sensor according to the related art, and FIG. 2 is a diagram illustrating a layout of a pixel of a 4T type CMOS image sensor according to the related art.

Referring to FIG. 1, a pixel 100 of a CMOS image sensor includes a PD 10 as a photoelectric conversion unit and four transistors 20, 30, 40, and 50.

The four transistors 20, 30, 40, and 50 are transfer, reset, drive, and select transistors, respectively. In addition, a load transistor 60 is electrically connected to an output end of the pixel 100.

In FIG. 1, FD denotes a floating diffusion unit, Tx denotes a gate voltage for the transfer transistor 20, RX denotes a gate voltage for the reset transistor 30, Dx denotes a gate voltage for the drive transistor 40, and Sx denotes a gate voltage for the select transistor 50.

As shown in FIG. 2, in a pixel of a related-art 4T CMOS image sensor, a device isolation layer is formed in a predetermined region to define an active region. A PD is formed in a wide portion of the active region, and gate electrodes 23, 33, 43, and 53 of the four transistors are formed overlapping the other portion of the active region.

That is, the gate electrodes 23, 33, 43, and 53 are formed for the transfer, reset, drive, and select transistors 20, 30, 40, and 50, respectively.

Here, source/drain regions of the transistors 20, 30, 40, and 50 are formed by implanting dopant ions into portions of the active region located between the gate electrodes 23, 33, 43, and 53.

FIGS. 3A to 3J are cross-sectional diagrams for explaining a method for manufacturing a CMOS image sensor according to the related art.

Referring to FIG. 3A, a low-concentration P− type epitaxial layer 62 is formed on a high-concentration P++ type semiconductor substrate 61 by an epitaxial growth process.

A buffer oxide layer 63 is formed on the epitaxial layer 62, and a nitride layer 64 is formed on the buffer oxide layer 63.

A first tetra ethyl ortho silicate (TEOS) layer 65 is formed on the nitride layer 64, and the resulting stacked structure is heat treated by annealing.

Referring to FIG. 3B, a first photoresist layer 66 is formed on the first TEOS layer 65 and is patterned by exposing and developing processes so as to define a device isolation region.

The first TEOS layer 65, the nitride layer 64, and the buffer oxide layer 63 are selectively removed using the patterned first photoresist layer 66 as a mask, so as to expose the device isolation region of the substrate.

Referring to FIG. 3C, the first photoresist layer 66 is removed, and the semiconductor substrate 61 is cleaned to remove contamination that may have formed.

A second TEOS layer is formed on an entire surface of the substrate 61 and is selectively removed by an etch back process. As a result, the second TEOS layer 67 remains on sidewalls of the stacked structures of the first TEOS layer 65, the nitride layer 64, and the buffer oxide layer 63.

Referring to FIG. 3D, the entire surface of the semiconductor substrate 61 is cleaned, and the epitaxial layer 62 is selectively removed using the first and second TEOS layers 65 and 67 as masks so as to form trenches 68 to a predetermined depth.

Here, the trenches 68 are formed to a predetermined depth from the top surface of the epitaxial layer 62 using a plasma gas.

Referring to FIG. 3E, a device isolation layer 69 is formed by filling the trenches 68 with an insulation material.

Then, the buffer oxide layer 63, the nitride layer 64, and the first and second TEOS layers 65 and 67 are removed.

Referring to FIG. 3F, a gate insulation layer 70 and a conductive layer (e.g., a high-concentration polycrystalline silicon layer) are sequentially deposited on an entire surface of the epitaxial layer 62 including the device isolation layer 69, and then the conductive layer and the gate insulation layer 70 are selectively removed so as to form a gate electrode 71.

Referring to FIG. 3G, a second photoresist layer 72 is formed on the entire surface of the semiconductor substrate 61 and is patterned to expose a blue, green, or red PD region.

N-type dopant ions are implanted into the epitaxial layer 62 to a low-concentration using the patterned second photoresist layer 72 as a mask so as to form a low-concentration n− type diffusion region 73 in the blue, green, or red PD region.

Referring to FIG. 3H, the second photoresist layer 72 is completely removed, and an insulation layer is deposited on the entire surface of the semiconductor substrate 61. Then, the insulation layer is etched back so as to form insulation sidewalls 74 on both sides of the gate electrode 71.

After that, a third photoresist layer 75 is formed on the entire surface of the semiconductor substrate 61 and is patterned by exposing and developing processes. As a result, the PD region is covered with the third photoresist layer 75, and a source/drain region of a transistor is exposed.

Then, n+ type dopant ions are implanted in the exposed source/drain region to a high concentration using the patterned third photoresist layer 75 as a mask so as to form an n+ type diffusion region (floating diffusion region) 76.

Referring to FIG. 3I, the third photoresist layer 75 is removed. Next, a fourth photoresist layer 77 is formed on the entire surface of the semiconductor substrate 61 and is patterned by exposing and developing so as to expose the PD region.

Then, p⁰ type dopant ions are implanted in the PD region where the n− type diffusion region 73 is formed using the patterned fourth photoresist layer 77 as a mask so as to form a p⁰ type diffusion region 78.

Referring to FIG. 3J, the fourth photoresist layer 77 is removed, and the semiconductor substrate 61 is heat treated so as to diffuse dopants implanted into each dopant diffusion region.

However, the related-art method has the following problems.

The forming of the device isolation layer requires complicated procedures. Furthermore, when the trenches are formed using plasma gas, lattice structure around the trenches can be damaged to cause junction leakage and interface trapping, thereby deteriorating the characteristics of the image sensor.

### BRIEF SUMMARY

Accordingly, embodiments of the present invention are directed to a method for manufacturing a CMOS image sensor that substantially obviates one or more problems due to limitations and disadvantages of the related art.

An object of embodiments of the present invention is to provide a method for manufacturing an improved CMOS image sensor by forming a device isolation layer through a simple process and preventing the lattice structure of the device isolation layer from being damaged.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a method for manufacturing a complementary metal oxide semiconductor (CMOS) image sensor, the method including: forming a mask layer on a semiconductor substrate to define a device isolation region; selectively removing the semiconductor substrate by wet etching using the mask layer as a mask so as to form a trench to a predetermined depth; forming a device isolation layer in the trench and removing the mask layer; forming a gate electrode on a gate insulation layer in an active region of the semiconductor substrate, the active region being defined by the device isolation layer; forming a photodiode (PD) region in the semiconductor substrate at one side of the gate electrode; and forming a floating diffusion region in the semiconductor substrate at the other side of the gate electrode.

### BRIEF DESCRIPTION OF THE DRAWINGS

The accompanying drawings, which are included to provide a futher understanding of the invention and are incorporated in and constitute a part of this application, illustrate embodiment(s) of the invention and together with the description serve to explain the principle of the invention.

FIG. 1 is an equivalent circuit diagram of a 4T type CMOS image sensor according to the related art.

FIG. 2 is a diagram illustrating a layout of a pixel of a 4T type CMOS image sensor according to the related art.

FIGS. 3A to 3J are cross-sectional diagrams for explaining a method for manufacturing a CMOS image sensor according to the related art.

FIGS. 4A to 4I are cross-sectional diagrams for explaining a method for manufacturing a CMOS image sensor according to an embodiment of the present invention

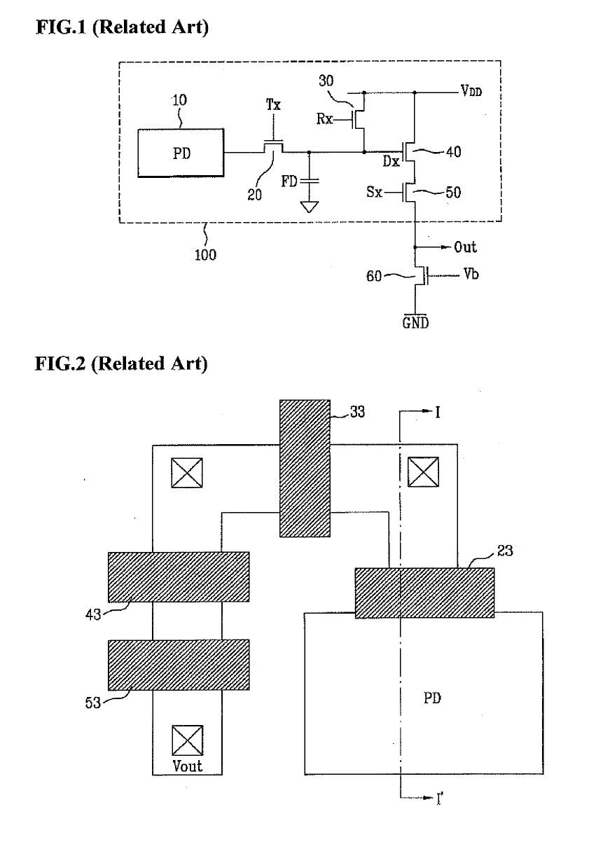

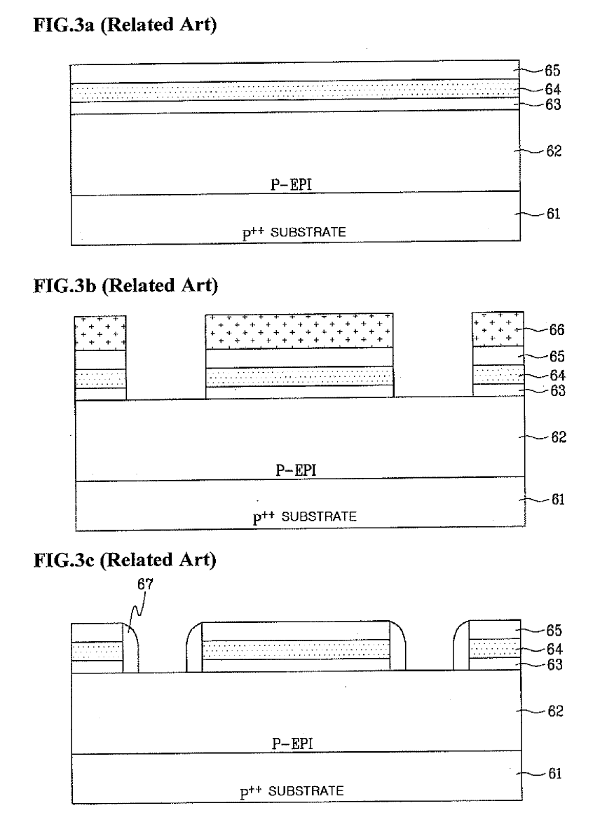

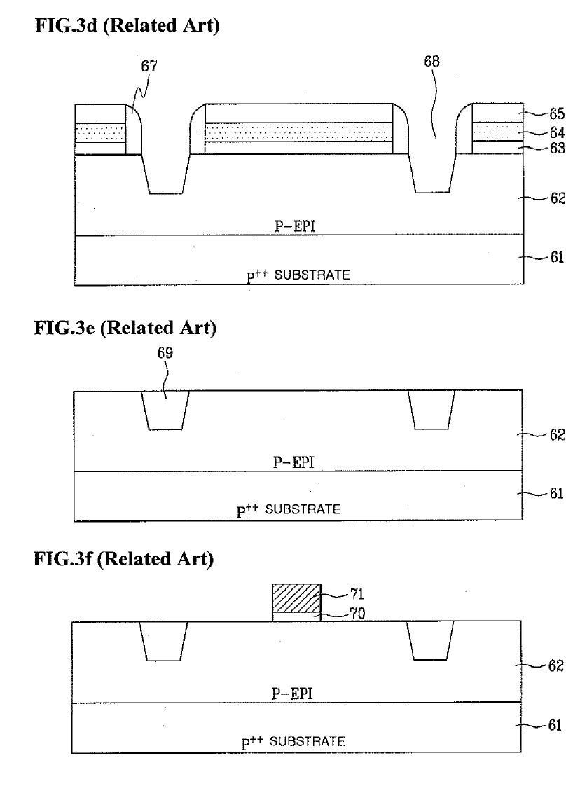

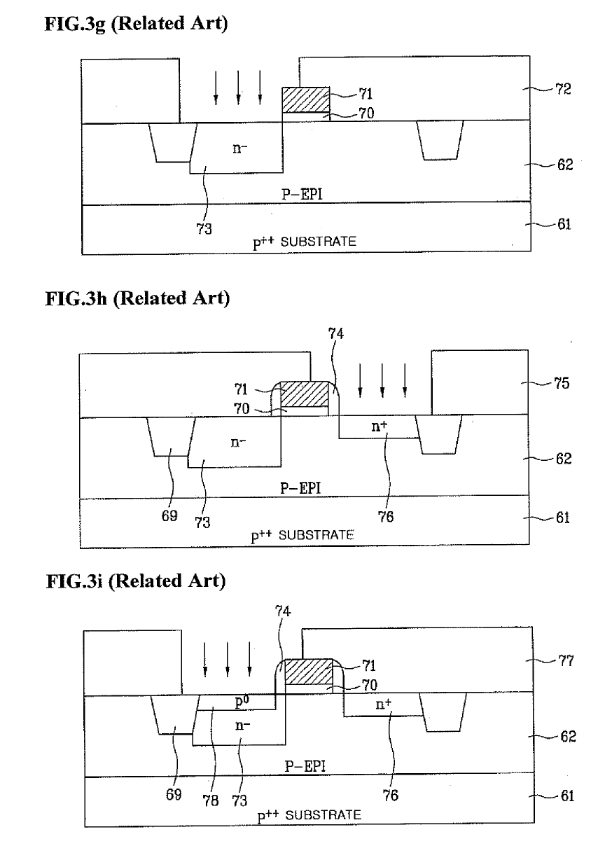

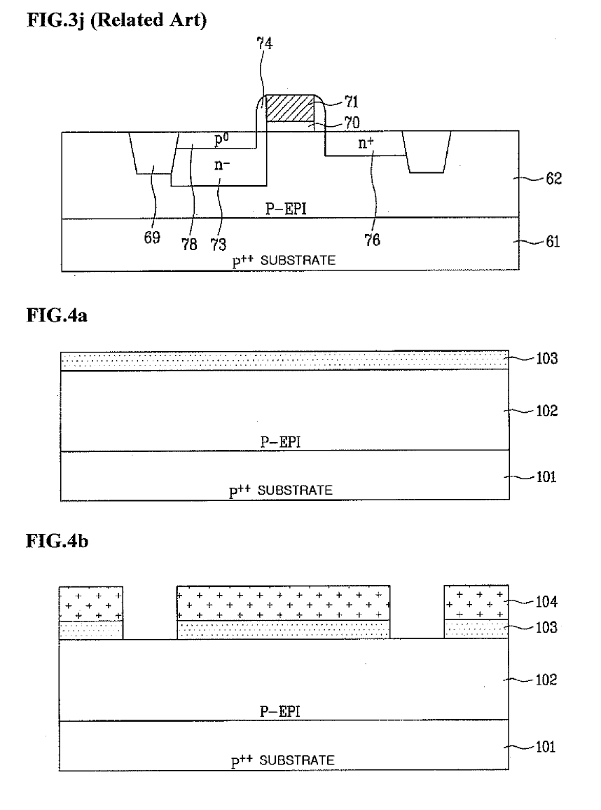

### DETAILED DESCRIPTION OF THE INVENTION

A method for manufacturing a CMOS image sensor according to preferred embodiments of the present invention will now be described with reference to the accompanying drawings.

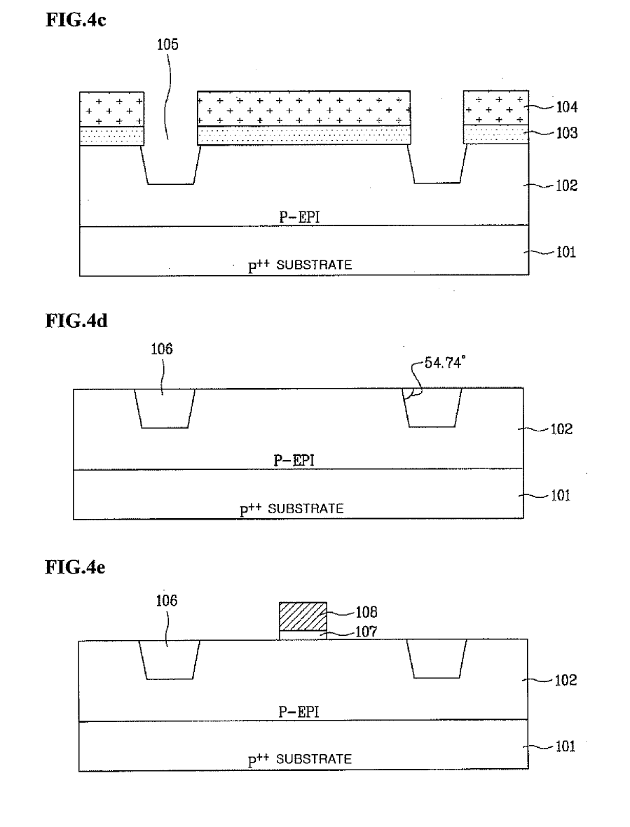

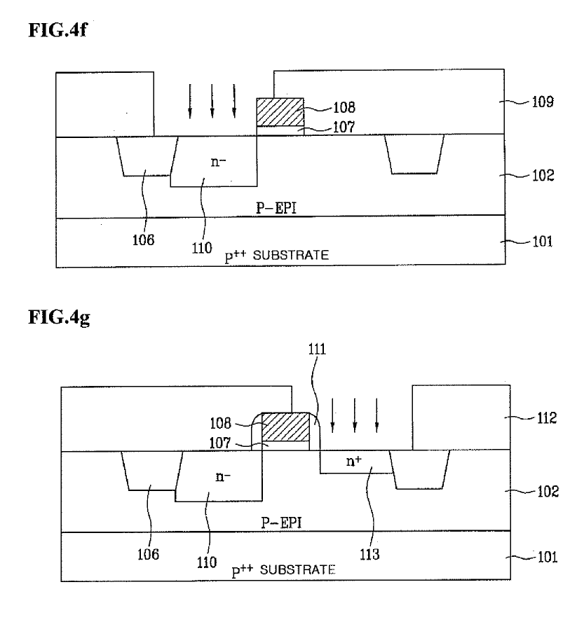

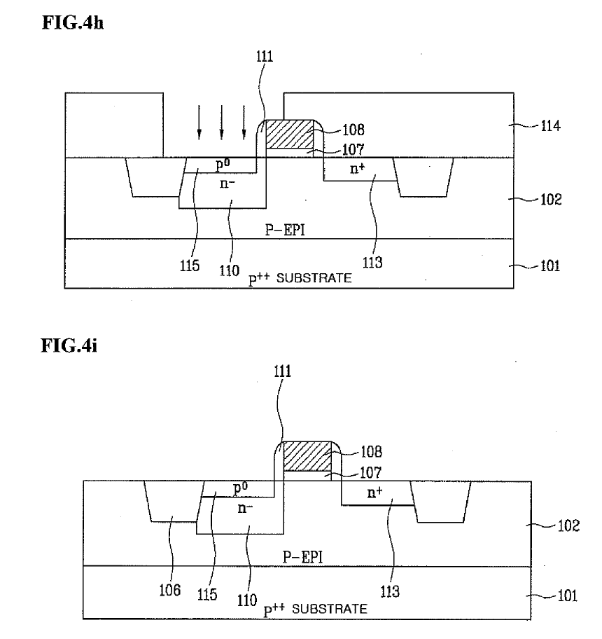

FIGS. 4A to 41 are cross-sectional diagrams for explaining a method for manufacturing a CMOS image sensor according to an embodiment of the present invention.

Referring to FIG. 4A, a low-concentration P− type epitaxial layer 102 can be formed on a high-concentration P++ type semiconductor substrate 101 by an epitaxial growth process.

Here, the epitaxial layer 102 is formed to increase the size and depth of a depletion region of a low-voltage PD so as to improve optical charge collecting ability and sensitivity of the low-voltage PD.

Next, a nitride layer 103 can be formed on an entire surface of the semiconductor substrate 101.

Referring to FIG. 4B, a first photoresist layer 104 can be formed on the nitride layer 103, and can be patterned by exposing and developing processes so as to define a device isolation region.

Then, the nitride layer 103 can be selectively removed using the patterned first photoresist layer 104 as a mask so as to open the device isolation region of the substrate.

Referring to FIG. 4C, the epitaxial layer 102 can be selectively removed by wet etching using the nitride layer 103 and the first photoresist pattern 104 as an etch mask so as to form trenches 105 to a predetermined depth in the substrate. In an embodiment, the first photoresist pattern 104 can be removed, and the semiconductor substrate 101 can be cleaned to remove contamination.

In a specific embodiment, tetra methyl ammonium hydroxide (TMAH) can be used for the wet etching process of forming the trenches 105.

In a further embodiment, the trenches 105 can be formed 0.24 μm wide and 0.7 μm deep.

Referring to FIG. 4D, a conductive material can be filled into the trenches 105 to form a device isolation layer 106, and the nitride layer 103 can be removed.

In an embodiment, the device isolation layer 106 can have a corner angle of about 54°. In a specific embodiment, the corner angle can be 54.74°.

Referring to FIG. 4E, a gate insulation layer 107 and a conductive layer (for example, a high-concentration polycrystalline silicon layer) can be sequentially formed on an entire surface of the epitaxial layer 102 including the device isolation layer 106.

The gate insulation layer 107 can be formed by, for example, thermal oxidation or chemical vapor deposition (CVD).

Then, the conductive layer and the gate insulation layer 107 can be selectively removed to form a gate electrode 108.

Here, the gate electrode 108 is a gate electrode of a transfer transistor.

Referring to FIG. 4F, a second photoresist layer 109 can be formed on the entire surface of the semiconductor substrate 101 including the gate electrode 108, and can be patterned by exposing and developing processes to expose a PD region.

Next, second conductive type (n− type) dopant ions can be implanted into the epitaxial layer 102 to a low concentration using the patterned second photoresist layer 109 as a mask, thereby forming an n- type diffusion region 110 in the PD region.

Referring to FIG. 4G, the second photoresist layer 109 can be removed, and an insulation layer is formed on the entire surface of the semiconductor substrate 101 including the gate electrode 108. Then, the insulation layer can be blanket etched to form insulation sidewalls 111 on sides of the gate electrode 108.

Thereafter, a third photoresist layer 112 can be formed on the entire surface of the semiconductor substrate 101 including the gate electrode 108, and can be patterned by exposing and developing processes to cover the PD region and expose a source/drain region (floating diffusion region).

Then, second conductive type (n+ type) dopant ions can be implanted into the exposed source/drain region to a high concentration using the patterned third photoresist layer 112 as a mask, thereby forming an n+ diffusion region (floating diffusion region) 113.

Referring to FIG. 4H, the third photoresist layer 112 can be removed, and a fourth photoresist layer 114 can be formed on the entire semiconductor substrate 101. Then, the fourth photoresist layer 114 can be patterned by exposing and developing processes to expose the PD region.

Thereafter, first conductive type (p⁰ type) dopant ions can be implanted in the n− type diffusion region 110 of the epitaxial layer 102 using the patterned fourth photoresist layer 114 as a mask to form a p⁰ diffusion region 115 in the surface of the epitaxial layer 102.

Referring to FIG. 4I, the fourth photoresist layer 114 can be removed, and the semiconductor substrate 101 can be heat treated to diffuse the ions in each diffusion region.

Thereafter, an image sensor can be completed by forming a color filter layer and a micro lens after a plurality of metal lines are formed (not shown).

As described above, according to the present invention, the method for manufacturing a CMOS image sensor has the following advantages.

The device isolation layer can be formed through a simple process. Furthermore, the lattice structure of the device isolation layer can be protected since the trenches are formed by wet etching, thereby preventing junction leakage and interface trapping.

It will be apparent to those skilled in the art that various modifications and variations can be made in the present invention. Thus, it is intended that the present invention covers the modifications and variations of this invention provided they come within the scope of the appended claims and their equivalents.

I claim:

1. A method for manufacturing a complementary metal oxide semiconductor (CMOS) image sensor, comprising:
forming a mask layer on a semiconductor substrate to define a device isolation region;
selectively removing a portion of the semiconductor substrate by wet etching using the mask layer as a mask to form a trench to a predetermined depth;
forming a device isolation layer in the trench and removing the mask layer;
forming a gate electrode on a gate insulation layer in an active region of the semiconductor substrate, the active region being defined by the device isolation layer;
forming a photodiode (PD) region in the semiconductor substrate at one side of the gate electrode; and
forming a floating diffusion region in the semiconductor substrate at another side of the gate electrode.

2. The method according to claim 1, wherein the wet etching is performed using TMAH (tetra methyl ammonium hydroxide).

3. The method according to claim 1, further comprising forming insulation sidewalls on sides of the gate electrode.

4. The method according to claim 1, wherein the device isolation layer has an upper corner angle of about 54°.

5. The method according to claim 1, further comprising forming an impurity region on the photodiode region doped with a conductive dopant different from that used for doping the photodiode region.

6. The method according to claim 1, wherein the mask layer is a nitride layer.
